(19) United States
(12) Patent Application Publication
(10) Pub. No.: US 2019/0049410 A1
(43) Pub. Date: Feb. 14, 2019

(54) EDDY CURRENT INSPECTION PROBE

(71) Applicant: Zetec, Inc., Snoqualmie, WA (US)

(72) Inventor: William Oren Wekell, Maple Valley, WA (US)

(21) Appl. No.: 16/076,827

(22) PCT Filed: Feb. 17, 2017
(86) PCT No.: PCT/US2017/018311

§ 371 Date: Aug. 9, 2018

Related U.S. Application Data
(60) Provisional application No. 62/297,330, filed on Feb. 19, 2016.

(51) Int. Cl. G01N 27/90; G21C 17/017; G01R 33/09; G01R 33/07

(52) U.S. Cl. CPC G01N 27/9033; G01N 27/9046; G01R 33/07; G01R 33/09; G21C 17/017

(57) ABSTRACT

A number of embodiments of inventive eddy current probes for non-destructive inspection of electrically conductive tubes are described. These include a bearing-centered probe, a spring loaded wheel-centered probe, a multi-part probe for curved tube inspection having limited excursion ball joints connecting the probe parts, and a 3D printed probe including features that are incapable of being manufactured through conventional casting or machining processes.

### CROSS-REFERENCE TO RELATED APPLICATION

This application claims the benefit under 35 U.S.C. § 371 of International Application No. PCT/US2017/018311, filed Feb. 17, 2017, which claims priority under 35 U.S.C. § 119 based on U.S. Provisional Patent Application No. 62/297,330 filed Feb. 19, 2016, the disclosure of which is incorporated by reference herein.

### BACKGROUND OF THE INVENTION

Steam generation for driving turbines has been an aspect of electrical power generation, for many decades. Fuel for steam generation can be hydrocarbon-based, such as coal-based, or based on nuclear fission. In either case, but especially in the case of fission-based steam generation, routine monitoring of the condition of high pressure steam tubes in steam generators is critical. For example, in fission-based steam generation, high pressure steam tubes separate radioactive water from non-radioactive water and any leak can be catastrophic. Steam tube inspection is generally conducted with cylindrically-shaped eddy current probes that are inserted into steam tube arrays and travel through the arrays attached to cabling while monitoring equipment records the eddy current response as the probe travels through the tubes. The probes include one or more coils of wire driven by the monitoring equipment for exciting an alternating magnetic field. The electromagnetic field produces eddy currents in the tubes, which can be measured either by a change in impedance of the excitation coil or by separate coils, hall-effect sensors or magneto-resistive sensors. Common problems affecting the ability to detect tube wear and flaws with eddy current probes include wobble of the probe while travelling through the tube and maintaining the probe evenly centered within the tube so that it is not too close to any one section of the tube wall.

Tube Centering Problem

Typical eddy current probes for non-destructive testing of heat exchanger tubing and the like are composed of a probe head supporting a plurality of sensing coils, a flexible plastic conduit with wiring and a connector providing a removable connection to testing equipment. Probe heads often incorporate features to center the coil assembly in the center of the tube under inspection. This centering reduces “lift-off”, where the probe moves away from the tube wall and such centering is important for maintaining good signal quality.

This centering function has been done in the prior art by machined plastic parts that incorporate a plurality of flexible fingers extending from the probe that apply an equal circumferential force to the inner wall of the tubing under inspection. But these machined plastic parts, typically called feet, have some significant limitations. These parts, which need to be flexible, are not durable and can be bent or broken by hard use or abuse. Additionally, because these parts bear against the tube wall, they are subject to wear as the sensor is moved in and out of hundreds of tubes which may involve thousands of feet of sliding friction wear. This may directly damage one or more of the feet. Alternatively, the movement may adversely affect the quality of the data from the probe if the wear is uneven across the plurality of feet used to center the probe. These effects can drive the sensor out of its centered position causing lift-off errors. Additionally, if the wear on the feet is even but substantial, the feet may no longer press against the tube wall and the sensor may become loose within the tube, which causes erratic movement and creates data quality issues.

Because of probe wear and degradation of signal quality from the probe, it may take many probes to complete a single heat exchanger inspection. Because these inspections occur in radioactive environments, the probes become irradiated and poorly performing probes ultimately become expensive nuclear waste due to failures of these feet.

One attempt to address the wear problem uses plastic feet that have a machined slug of ceramic glued into each petal of the foot to limit wear. Drawbacks of this design include problems with affixing the wear element, the cumbersome assembly of a custom part, the presenting of a sharp edge to the tube wall and the spring element has fragility and lifespan issues associated with a plastic part.

Curve Centering Problem

As described above, probe heads often incorporate feet or other features that center the coil assembly in the center of the tube under inspection. i.e., align the axis of the probe with the axis of the tube. Prior art probes, e.g., FIG. 7, have fixed feet 701 rigidly connected on either side of a coil body housing a plurality of coils 703. The feet on these probes center work relatively well in straight tubing, but most heat exchanger tubing has curved sections. These curved sections may have larger residual manufacturing stresses than straight sections and are at least as likely if not more likely than straight tube sections to develop flaws such as pitting or cracking. In prior art devices, however, as shown in FIG. 7, the geometry of the straight support between the feet 701 and the bobbin 702 on which the coils 703 are wound and the curved tubing section, creates lift-off on the outside of the curve that degrades signal quality.

Machinability Problem

Manufacturing prior art eddy current probe heads involves machining component parts such as a bobbins on which sensing coils are wound; feet, which center the coils in the tube (for data quality); parts to allow flexing of the head around tubing bends; and coupling parts to join the bobbin assembly to the conduit tubing. Each of these parts requires separate programming and expensive machining operations to tight tolerances in order to fit together properly. With traditional machining methods, the parts' requirements are too complex to integrate all the features into a single construction. A substantial amount of hand assembly is then required to construct the probe head assembly leading to a time-consuming expensive device that also has the potential for flaws due to human error.

### SUMMARY OF THE INVENTION

An aspect of the invention includes an eddy current probe for insertion into and non-destructive testing of an electrically conductive cylindrical tube having an axis wherein the tube includes straight and curved portions. The eddy current probe includes: a sensor portion having a sensor portion axis and an axial center; a front sensor guide comprising first centering feet; and

a rear sensor guide comprising second centering feet, the sensor portion is attached to the front sensor guide with a first limited travel ball joint, the sensor portion is also attached to the rear sensor guide with a second limited travel ball joint. The location of the limited travel ball joints with respect to the first and second centering feet and with further respect to the axial center of the sensor portion is configured to position the sensor portion so as to align the sensor portion axis with the axis of the tube inner walls within both straight and curved portions of the tube under test. In a further aspect of the invention, the sensor portion comprises a coil bobbin and coil windings. In a further aspect of the invention the sensor portion comprises an array of coils. In a further aspect of the invention, the sensor portion comprises a hall-effect or magneto-resistive electromagnetic field sensor. In a further aspect of the invention, the sensor portion comprises an excitation coil and either a sensing coil, a sensing coil array, a hall-effect or magneto-resistive electromagnetic field sensor or an array of hall-effect or magneto-resistive electromagnetic field sensors. In a further aspect of the invention, each of the first and second centering feet includes a wheel. In a further aspect of the invention, each of the front and rear sensor guides further comprises a wear skid.

An aspect of the invention includes an eddy current probe for insertion into and non-destructive testing of an electrically conductive cylindrical tube having an axis wherein the tube includes straight and curved portions. The eddy current probe of this aspect includes: a first sensor portion having a first sensor portion axis and a first sensor portion axial center; a second sensor portion having a second sensor portion axis and a second sensor portion axial center; a front sensor guide comprising first centering feet; and a rear sensor guide comprising second centering feet. The first sensor portion is attached to the front sensor guide with a first limited travel ball joint and to the second sensor portion with a second limited travel ball joint. The second sensor portion is attached to the rear sensor guide with a third limited travel ball joint, and locations of the first and third limited travel ball joints with respect to the first and second centering feet and with further respect to the first and second axial centers of the first and second sensor portions, respectively, are configured to position the first and second sensor portions to align each of the first and second sensor portion axes with the axis of the tube inner walls within both straight and curved portions of the tube under test. In a further aspect of the invention, one of the first or second sensor portions includes a coil bobbin and coil windings. In a further aspect of the invention, one of the first or second sensor portions includes an array of coils. In a further aspect of the invention, one of the first or second sensor portions includes a hall-effect or magneto-resistive electromagnetic field sensor. In a further aspect of the invention, one of the first or second sensor portions includes an excitation coil and the other of the sensor portions includes either a sensing coil, a sensing coil array, a hall effect or magneto-resistive electromagnetic field sensor or an array of hall-effect or magneto-resistive electromagnetic field sensors. In a further aspect of the invention each of the centering feet includes a wheel. In a further aspect of the invention, each of the front and rear sensor guides further includes a wear skid.

An aspect of the invention includes an eddy current probe for insertion into and non-destructive testing of an electrically conductive cylindrical tube having an axis wherein the tube includes straight and curved portions. The eddy current probe includes: a sensor portion having a sensor portion axis and an axial center; a front sensor guide having a front sensor guide axis; and a rear sensor guide having a rear sensor guide axis. The sensor portion is attached to the front sensor guide with a first limited travel ball joint, and the sensor portion is also attached to the rear sensor guide with a second limited travel ball joint. The front sensor guide includes first and second sets of circumferentially-arranged balls arranged to align the front guide axis with the axis of the tube, and the rear sensor guide includes second and third sets of circumferentially-arranged balls arranged to align the rear guide axis with the axis of the tube. The location of the first and second limited travel ball joints with respect to the first and second sets of circumferentially-arranged balls and with further respect to the axial center of said sensor portion is configured to position the sensor portion so as to align the sensor portion axis with the axis of the tube inner walls within both straight and curved portions of the tube under test. In a further aspect of the invention, each set of circumferentially-arranged balls is spring-loaded such that the balls are urged toward the tube inner wall. In a further aspect of the invention, each set of circumferentially-arranged balls is urged toward the tube wall by a conical ramp arranged to prevent the balls from rotating while the eddy current probe is traveling through the tube. In a further aspect of the invention, the eddy current probe includes a tube diameter measurement coil, wherein at least one of the sets of circumferentially arranged balls is urged toward the conical ramp by an electrically conductive ring or washer, and wherein axial location of the ring or washer is detected by the tube diameter measurement coil and wherein the detected location is related to tube inner diameter. In a further aspect of the invention, the sensor portion comprises a coil bobbin and coil windings. In a further aspect of the invention, the sensor portion comprises an array of coils.

### BRIEF DESCRIPTION OF THE DRAWINGS

FIG. 1 is a 3D drawing of an exemplary bearing-centered probe;

FIG. 2 is top and side views of the probe of FIG. 1;

FIG. 3 is a cross sectional view of the probe of FIG. 1 about section line AA;

FIG. 4 is a side view of components of the probe of FIG. 1;

FIG. 5 is an exploded view of a portion of the probe of FIG. 1;

FIG. 6 is a 3D drawing of an exemplary bearing-centered probe incorporating tube inner diameter measuring;

FIG. 7 is a cross section of a prior art probe in a curved section of tube under inspection;

FIG. 8 is a 3D drawing of an exemplary curve-centered probe;

FIG. 9 is a 3D front view of the probe of FIG. 8;

FIG. 10 is a cross-section view of the probe of FIG. 8, shown in in a tube under inspection;

FIG. 11 is a 3D drawing of an exemplary 3D printed eddy current probe;

FIG. 12 is a front view and cross section view of the probe of FIG. 11; and

FIG. 13 is a side view of the probe of FIG. 11.

### DESCRIPTION OF THE PREFERRED EMBODIMENTS OF THE INVENTION

### Bearing Centered Probe and Inner Diameter Measurement Device

An aspect of the invention includes applying centering forces to an eddy current probe in a tube under test that is durable and remains accurate. Durable components with limited free travel are brought to bear against the tube wall under test and are forced against the wall by a compliant spring feature.

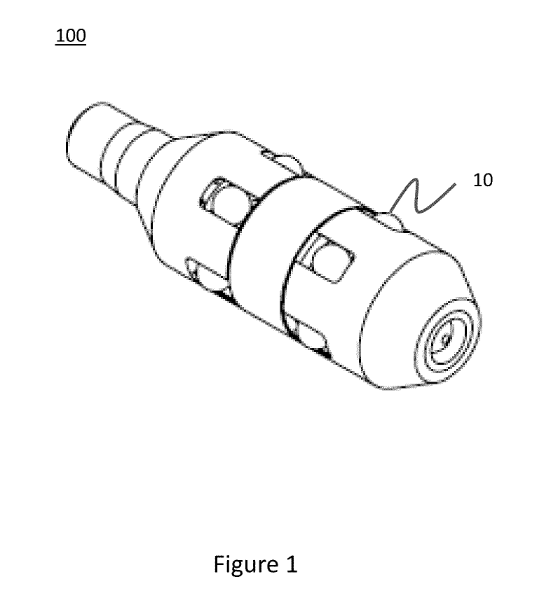

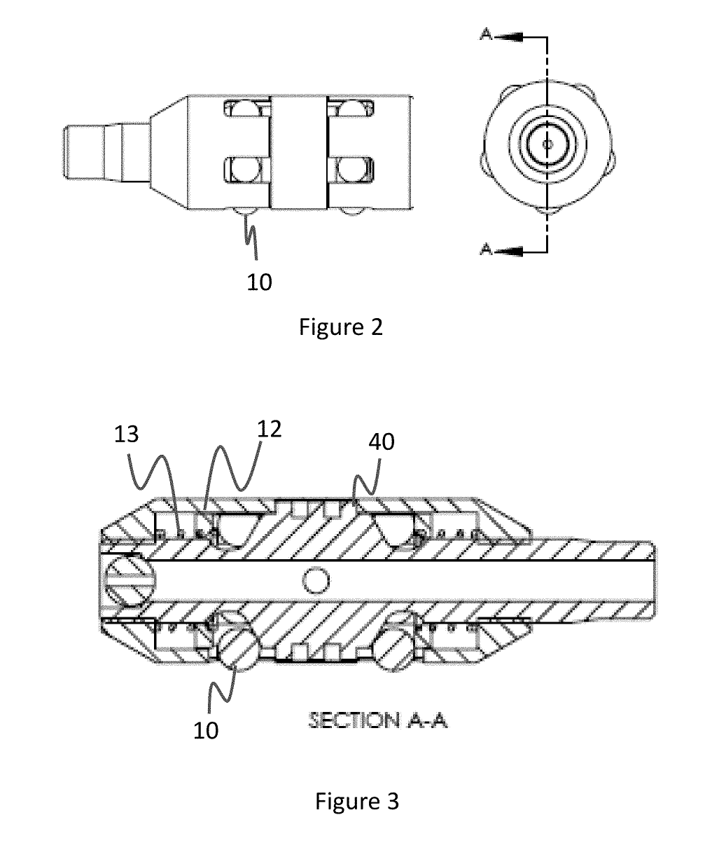

In a preferred embodiment, shown in FIGS. 1-5, a ball bearing and a metal spring assembly are used to center the probe 100. In an embodiment, the ball bearings are made of zirconium oxide. But it should be clear to one skilled in the art that the free traveling durable bodies may be spherical, wheel-shaped, disk-shaped, flat, ovoid or some other shape, and may still practice this invention and be within the scope of this disclosure. The ball bearings, also referred to herein as balls, or their equivalent are limited travel bodies that are not affixed, but retained by the probe head and separate the friction element from the spring element of the centering feature.

Zirconium is regularly used in nuclear installations and is typically harder than the tube under inspection and also harder than inclusion materials such as magnetite, which a probe might encounter inside a tube. Zirconium is also less brittle than other nonmagnetic bearing materials such as silicon carbide, silicon nitride or aluminum oxide and this helps avoid breakage when encountering intermittent high forces. These bearings are inexpensive, as they are already produced in large quantities for corrosive bearing applications.

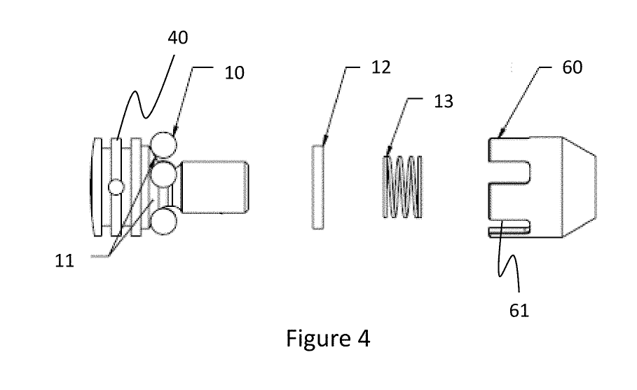

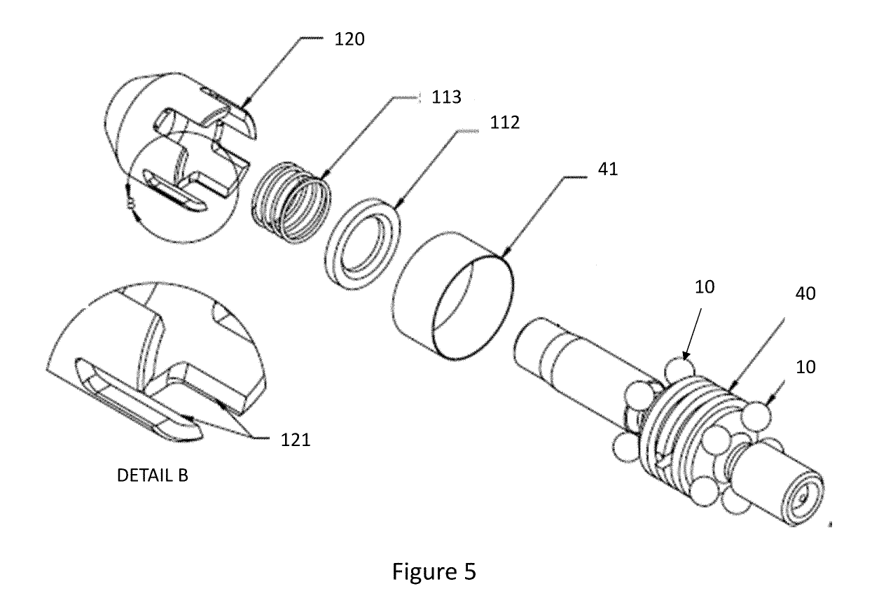

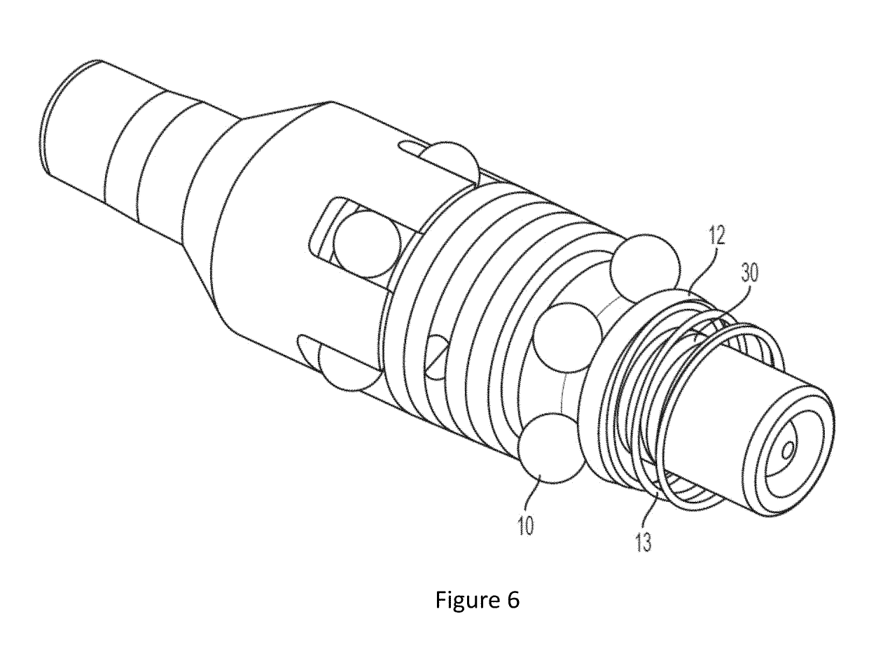

In embodiments, as shown in FIGS. 1-5, a plurality of balls 10 is arranged circumferentially in an eddy current probe. In the preferred embodiment, this would consist of one or several rings of such balls. As shown in FIG. 4, which is a front portion of an exemplary ball-centered probe, the balls 10 arranged in a ring are urged with a single spring 13, covered by a spring sleeve 41, via a washer 12 to apply consistent equal centering force on each ball 10. A ramp 11 on the bobbin 40 deflects the spring force against the balls 10 into even circumferential pressure. In preferred embodiments, the bobbin is made of nylon. Front cover 60 has slots 61 that limit the ball travel and retain the balls 10 when the probe 100 is not in a tube. FIG. 5 shows a back cover 120 and a detail of the slots 121 in the back cover, the slots 21 having a sloped face 121 on which the balls 10 are guided. In a preferred embodiment, shown in FIG. 5 two rings of balls 10 are trapped in cages (e.g. back cover 120 and sloped faces 121 forming a rear cage) that allow them limited freedom of movement, while in actual use the balls 10 are urged against the tube wall so the ball contact with the slots 21 is minimal. In an exemplary embodiment as shown in FIG. 5, two rings of balls 10 center the probe 100 at the front and back to keep it aligned axially within the tube. Also shown in FIG. 5 is the rear portion of the probe 100 shown in FIG. 4, includes rear cover/ball guide 120, rear ball spring 113 and rear ball washer 112. When the sensor is outside the tube, the rear cover/ball guide 120 limits the travel of the balls 10 such that they are unable to escape the assembly, as the windows in which they open to the tube are smaller than the ball diameter of the ball. This feature is shown in the Detail B in FIG. 5.

Aspects described herein provide some significant advantages over the current practice. Because the balls 10 are harder than the tube material, they are subject to much less wear than the prior art plastic feet. The balls do not damage the tubing because they are extremely smooth, have a large negative rake angle and apply little force to the tube wall. The balls also apply a higher amount of friction against the nylon bobbin than against than the tube wall, which allows them to slide along the tube wall, as opposed to rolling, under normal test conditions. This is due in part to the shape of the ramp 11, which can be designed to contact more of the ball surface than the flat inner face of the tube under inspection. Also, the nylon being more pliable than the tube will deform slightly, also creating a larger bearing surface area than that of the ball to tube contact area. On entering and exiting the tube sheet, the balls are disrupted and move, exposing different portions of their surface to the tube wall. This limits and evens out wear to the balls 10 and because the balls 10 remain relatively smooth all over they do not substantially wear out. This reduced friction and wear provide a better product with longer probe life, better data from the probe and less nuclear waste. Additionally, the force applied by a metal spring can remain more consistent over the longer life of the probe than the prior art self-sprung plastic feet.

In a further embodiment, the probe can be made using wheels instead of balls as the tube contacting members. The wheels do not slide against the tube wall as described above for the balls 10, but rather, the wheels roll against the tube inner wall. The wheels serve the same function as the balls 10. That is, the wheels isolate the wear and spring functions of the centering feature. The wheels may also provide less risk of damaging the tube under test and, by transferring the friction to the axle, be more durable than the sliding balls 10 described above. Additionally, the life of the probe can be limited by a controlled degradation of the wheel axle, since the axle and the bearing surface of the wheel riding on the axle are known materials and have known hardnesses, as opposed to the somewhat less controlled situation where the centering balls 10 slide through tubes of varying surface roughness and materials due to deposits and corrosion.

In a further embodiment, shown in FIG. 6, a diameter measuring coil 30 is included to measure the position of the bearing washer 12. By sensing the axial position of the bearing washer 12, which is urged by a spring 13 against the balls 10 that contact the inner wall of the tube under inspection, the probe functionality can be expanded to include measurement of the inner diameter of the tube under inspection. This embodiment adds significant functional value to the product because general wall thinning erosion is a common failure mode of heat exchanger tubing, and while eddy current technology is good for measuring cracks, pits and local flaws, it is not well suited to measuring large or slowly changing features such as wall thickness. By making the washer 12 that communicates the spring 13 force to the zirconium balls 10 conductive, its movement axially as the balls 10 move circumferentially along a conical ramp, following the tube wall, can be recognized and measured by a sensing coil 30. While hole-diameter measuring devices using bearings and conical or similarly shaped ramps may be generally known in the art, such concepts are not used in an eddy current inspection probe wherein the bearings are also adapted for centering the probe within the tube under inspection. Example patents include U.S. Pat. No. 2,369,319 and U.S. Pat. No. 4,851,773, which use a linear variable differential transformer (LVDT) to sense position of the bearings. Also relevant to the concept of using bearings to guide a measurement device in a tube is U.S. Pat. No. 8,390,278.

### Curve Centered Probe

Aspects described herein also provide a construction that maintains the eddy current probe coils in the probe head relative to the center of the tube under test whether in either a straight or curved tube section. By articulating the feet in relationship to the coil body, better coil positioning geometry can be achieved which results in better test data.

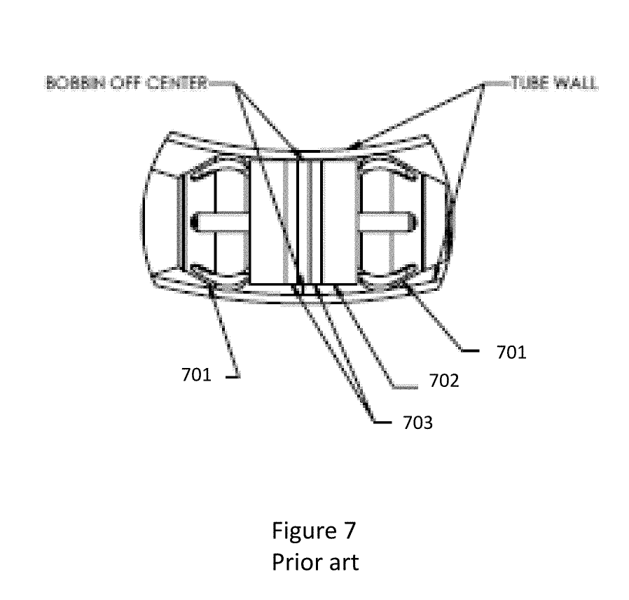

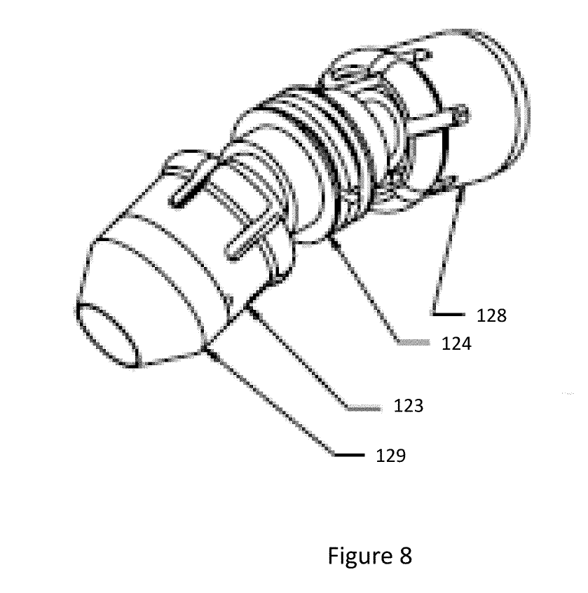

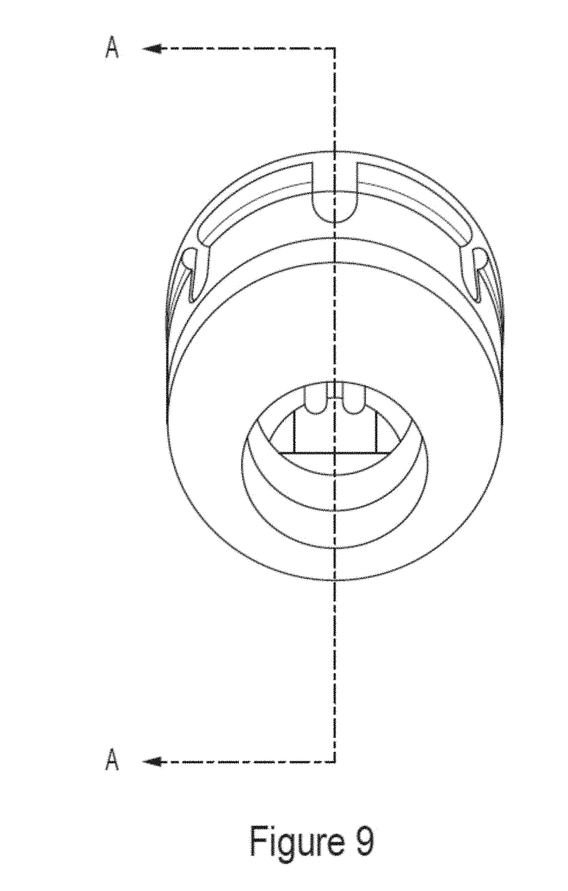

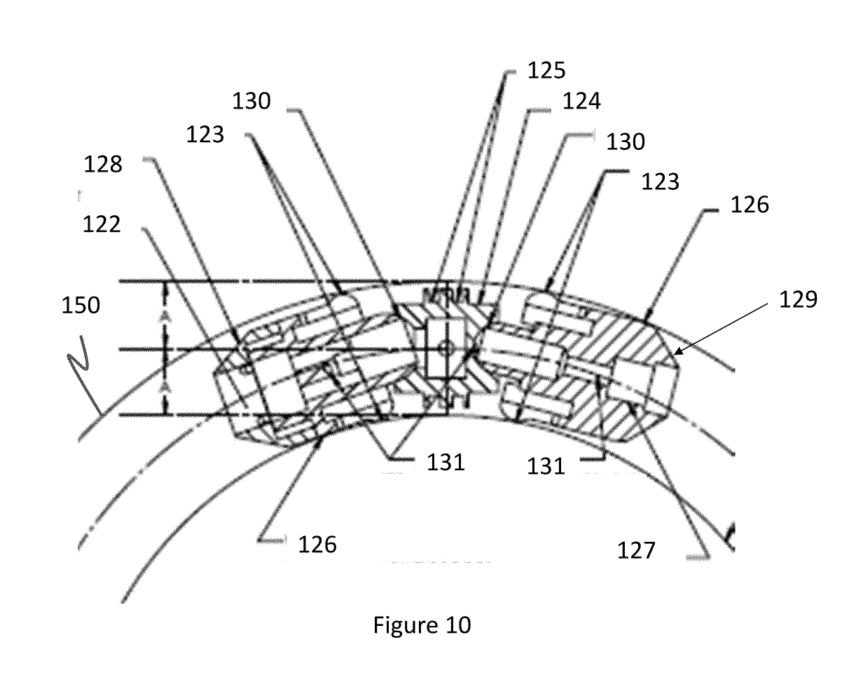

In a preferred embodiment, shown in FIGS. 8-10, ball joints 110 are built into the connections between front and back end pieces 128, 129 and the coil body 124. The front and back end pieces each have their own tube-centering mechanism 123, which can be feet, or spring loaded balls or wheels as described above. By positioning the axial centers of the ball joints 110 a specific distance from the center of the coil body 124? and by also taking account of the distance from the ball joint centers to the position where the centering feet 2 meet the tube wall under test, the central portion of the coil body is held more closely centered in the tube in a curved section of tubing than is the case in the single piece prior art probe, shown for example, in FIG. 7. The design distance between the ball joint centers and the coil body centers, as well as the distance between the ball joint centers and the centering feet is dependent on tube diameter and expected tube curvature radii for the application at hand. This specific distance creates leverage which approximates and cancels the foot position deflection resulting from the curvature of the tube under test. As shown in the cross-section view in FIG. 10, with the location of the ball joints 130 relative to the coil body 124 properly set, the coil body 124 is held in the middle of the tube wall 150, equidistant from the inner and outer perimeters of the curved section. Other elements in FIG. 10 include an array or coil body 124, coil grooves 125, wear skids 126, a space for a strain wire spring for tension of the strain wire 127, a conduit retainer 128, a space for entry of a coaxial conduit 122, and space for spring and strain wire guides 131.

In the preferred embodiment, to account for a separate bobbin coil body and array coil body, three limited rotation joints can be used as disclosed for the two joints show in FIGS. 8-10. It should be clear, however, to one skilled in the art that a bobbin coil body, an array coil body, which comprises an array of coils, which may be sensing, excitation or combined sensing and excitation coils, a combined bobbin/array, a unique coil assembly, a magnet sensing element such as a hall effect or magneto-resistive element, ultrasonic sensing element, or any combination of these or similar sensors may be held between end pieces with the ball joints as described herein and still practice this invention and be within the scope of this disclosure. Note that FIGS. 8-10 show a combined bobbin and array coil body and hence have only two ball joints 130.

Each of the two feet 123 in end pieces 128, 129 work independently and differently to follow the tube wall. Each foot 123 uses its centering features in conjunction with a wear skid area 126. The foot 123 is oriented by the normally straight strain wire or coax conduit to cock against the wear skid in a curved tube section. The changes in angular orientation of the foot position the bobbin. The geometric location of the ball joints 130 in relation to the centering feet and the angle of inclination of the foot are chosen to leverage and nullify forces that would otherwise drive the measurement sensing coils off center and degrade the quality of measurement.

### 3D Printed Probe

In an exemplary embodiment of the current invention, the functionality of supporting, centering, bending and connecting features of individual parts are integrated into a into a complex single part by using an additive process, such as three dimensional (3D) printing technology. The single part as disclosed herein cannot be manufactured through traditional subtractive processes such as mill and lathe operations, but is now possible with 3D printing processes.

Many types of 3D printing technology are currently available. But most of these do not satisfy the criteria of a successful probe. The construction needs to be a precise shape, durable, and of a material type acceptable to particular industries such as the nuclear steam generation market.

Fused deposition modeling (FDM) is typically too coarse and lamination boundaries are weak. Stereolithography (SLA) is typically not durable and is expensive. Polyjet constructions are brittle, prone to distortion and lack long term durability. Most additive processes produce unacceptable parts.

In a preferred embodiment, a laser sintered nylon 3D printing process is used to construct the probe head, but it is understood that other printing processes, and material formulations may be used and still meet the intent of this disclosure. In an exemplary embodiment, the part is made using uses a sintering machine produced by EOS (Germany) and uses a powdered nylon 12 material, PA 2201, also available from EOS. Nylon is a common material used in probes and accepted by power generation customers, but other suppliers of sintering machines and material may be substituted to achieve similar results.

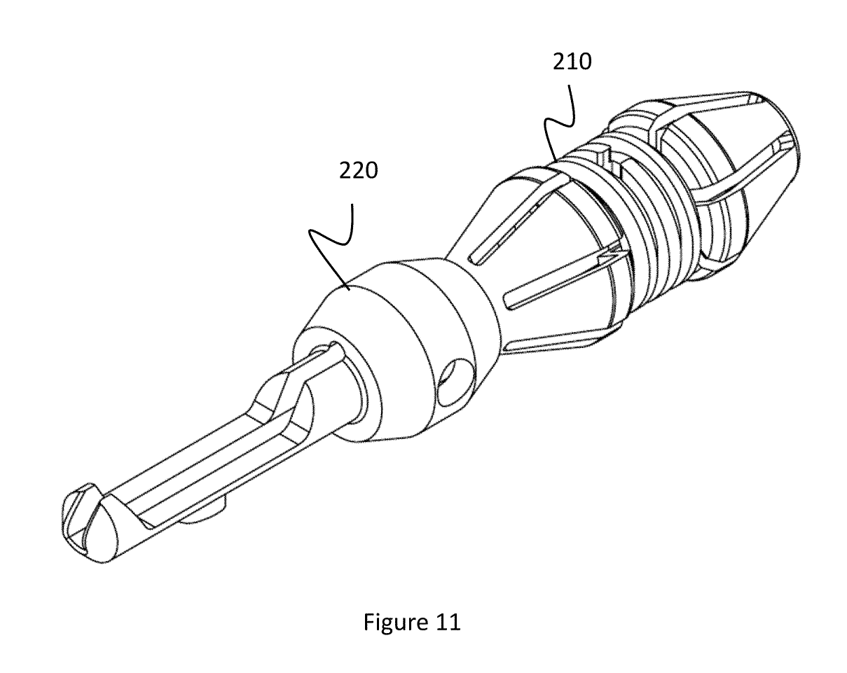

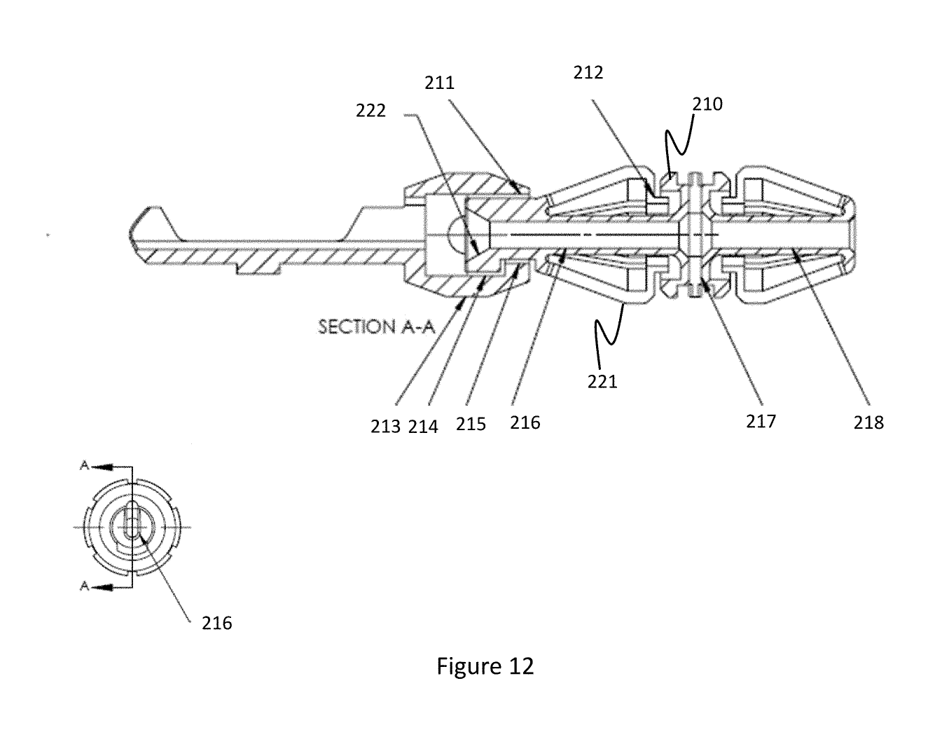

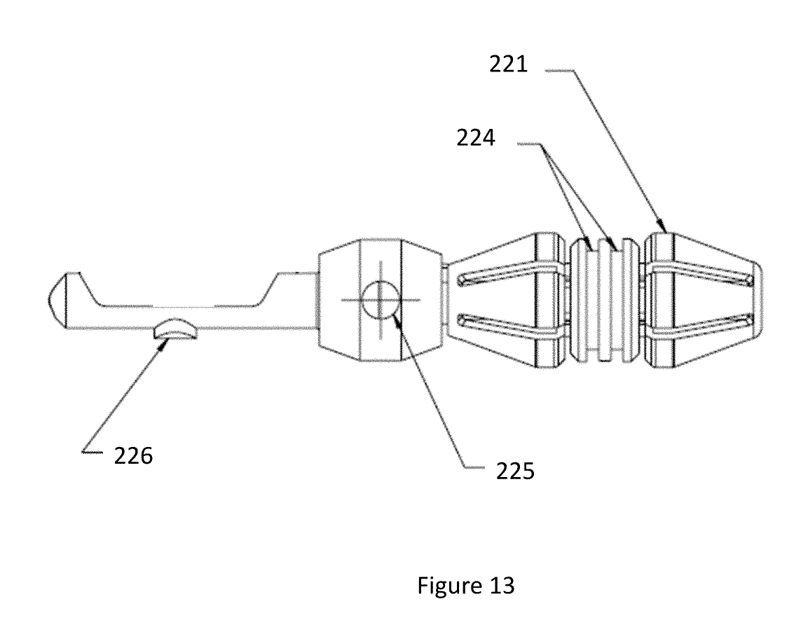

In an embodiment, shown in FIGS. 11-13, the sensor coil section 210 is not attached to the cable coupler section 220 even though the parts are manufactured together in the 3D printing process, The separation between these two parts, is seen in cross section FIG. 12. This feature allows a limited relative movement between these sections. The sensor is not mechanically joined to the coupler but captured and allowed to float freely within a limited range of motion. This serves the purpose of reducing the side load on the centering feet 221 and reducing wear on the feet 221, and also to isolate the sensor element from the tubing and its normal curvature which can push the sensor off center and degrade the quality of the test data as described above. This is particularly useful in portions of the tube under inspection that are curved, allowing the probe head to freely follow the tube wall unencumbered by the support cabling.

Additional features in the exemplary embodiment include: a tube-riding wear feature 213, clearance for evacuation of un-sintered material 214, anti-rotation key 215, coaxial cable wiring channel 216, magnet wiring channel 217, coaxial cable access 218 (in manufacture, the coaxial cable and magnet wire are lead out the tip and soldered and then slipped back inside the probe head), centering foot travel limits 212 to limit travel of the centering feet and keep them from being bent back and ripped out, a limited-excursion joint 211 that isolates the sensor from the conduit side forces and allows limited cornering in bent tubing, bobbin coil winding grooves 224, coax cable bending strain relief 222, two holes to clear unsintered material after part building, one on both sides 225, and snap latch 226 to secure probe head into a cable conduit hole (not shown).

I claim:

1. An eddy current probe for insertion into and non-destructive testing of an electrically conductive cylindrical tube having an axis wherein the tube includes straight and curved portions, the eddy current probe comprising:
a sensor portion having a sensor portion axis and an axial center;
a front sensor guide comprising first centering feet; and
a rear sensor guide comprising second centering feet,
said sensor portion being attached to said front sensor guide with a first limited travel ball joint,
said sensor portion being attached to said rear sensor guide with a second limited travel ball joint,
wherein location of said limited travel ball joints with respect to said first and second centering feet and with further respect to said axial center of said sensor portion being configured to position said sensor portion so as to align said sensor portion axis with the axis of the tube inner walls within both straight and curved portions of the tube under test.

2. The eddy current probe of claim 1, wherein said sensor portion comprises a coil bobbin and coil windings.

3. The eddy current probe of claim 1, wherein said sensor portion comprises an array of coils.

4. The eddy current probe of claim 1, wherein said sensor portion comprises a hall effect or magneto-resistive magnetic field sensor.

5. The eddy current probe of claim 1, wherein said sensor portion comprises an excitation coil and either a sensing coil, a sensing coil array, a hall effect or magneto-resistive electromagnetic field sensor or an array of hall effect or magneto-resistive electromagnetic field sensors.

6. The eddy current probe of claim 1, wherein each of said first and second centering feet comprises a wheel.

7. The eddy current probe of claim 1, wherein each of said front and rear sensor guides further comprises a wear skid.

8. An eddy current probe for insertion into and non-destructive testing of an electrically conductive cylindrical tube having an axis wherein the tube includes straight and curved portions, the eddy current probe comprising:
a first sensor portion having a first sensor portion axis and a first sensor portion axial center;
a second sensor portion having a second sensor portion axis and a second sensor portion axial center;
a front sensor guide comprising first centering feet; and
a rear sensor guide comprising second centering feet,
said first sensor portion being attached to said front sensor guide with a first limited travel ball joint and to said second sensor portion with a second limited travel ball joint;
said second sensor portion being attached to said rear sensor guide with a third limited travel ball joint, and
wherein locations of said first and third limited travel ball joints with respect to said first and second centering feet and with further respect to said first and second axial centers of said first and second sensor portions, respectively, are configured to position said first and second sensor portions so as to align each of said first and second sensor portion axes with the axis of the tube inner walls within both straight and curved portions of the tube under test.

9. The eddy current probe of claim 8, wherein one of said first or second sensor portions comprises a coil bobbin and coil windings.

10. The eddy current probe of claim 8, wherein one of said first or second sensor portions comprises an array of coils.

11. The eddy current probe of claim 8, wherein one of said first or second sensor portions comprises a semiconductor magnetic field sensor.

12. The eddy current probe of claim 8, wherein one of said first or second sensor portions comprises an excitation coil and the other of said sensor portions comprises either a sensing coil, a sensing coil array, a hall effect or magneto-resistive electromagnetic field sensor or an array of hall-effect or magneto-resistive electromagnetic field sensors.

13. The eddy current probe of claim 8, wherein each of said centering feet comprises a wheel.

14. The eddy current probe of claim 8, wherein each of said front and rear sensor guides further comprises a wear skid.

15. An eddy current probe for insertion into and non-destructive testing of an electrically conductive cylindrical tube having an axis wherein the tube includes straight and curved portions, the eddy current probe comprising:
a sensor portion having a sensor portion axis and an axial center;
a front sensor guide having a front sensor guide axis; and
a rear sensor guide having a rear sensor guide axis,
said sensor portion being attached to said front sensor guide with a first limited travel ball joint,
said sensor portion being attached to said rear sensor guide with a second limited travel ball joint,
said front sensor guide comprising first and second sets of circumferentially-arranged balls arranged to align said front guide axis with the axis of the tube, and
said rear sensor guide comprising second and third sets of circumferentially-arranged balls arranged to align said rear guide axis with the axis of the tube,
wherein location of said first and second limited travel ball joints with respect to said first and second sets of circumferentially-arranged balls and with further respect to said axial center of said sensor portion being configured to position said sensor portion so as to align said sensor portion axis with the axis of the tube inner walls within both straight and curved portions of the tube under test.

16. The eddy current probe of claim 15, wherein each set of circumferentially-arranged balls is spring-loaded such that said balls are urged toward the tube inner wall.

17. The eddy current probe of claim 16, wherein each set of circumferentially-arranged balls is urged toward the tube wall by a conical ramp arranged to prevent said balls from rotating while the eddy current probe is traveling through the tube.

18. The eddy current probe of claim 17, further comprising a tube diameter measurement coils, wherein at least one of said sets of circumferentially arranged balls is urged toward said conical ramp by an electrically conductive ring or washer, and wherein axial location of said ring or washer is detected by said tube diameter measurement coil and wherein said detected location is related to tube inner diameter.

19. The eddy current probe of claim 15, wherein said sensor portion comprises a coil bobbin and coil windings.

20. The eddy current probe of claim 15, wherein said sensor portion comprises an array of coils
